(19) United States
(12) Patent Application Publication
(10) Pub. No.: US 2023/0278589 A1
(43) Pub. Date: Sep. 7, 2023

(54) AUTONOMOUS DRIVING SENSOR SIMULATION

(71) Applicant: WOVEN BY TOYOTA, INC., Tokyo (JP)

(72) Inventor: Linyu SUN, Miyoshi City (JP)

(73) Assignee: WOVEN BY TOYOTA, INC., Tokyo (JP)

(21) Appl. No.: 17/687,774

(22) Filed: Mar. 7, 2022

(51) Int. Cl. B60W 60/00; B60W 30/10; B62D 15/02

(52) U.S. Cl. CPC B60W 60/0017; B60W 30/10; B62D 15/021; B60W 2554/4049

(57) ABSTRACT

A method of simulating a sensor in an autonomous driving simulation includes obtaining values for a plurality of attributes of a target object to be sensed by a sensor simulator in the autonomous driving simulation. The sensor simulator may simulate an active sensor that outputs rays to an object and receives reflections of the rays from the object. The method also includes inputting the obtained values for the plurality of attributes to a predetermined reflection rate table to obtain a reflection rate mapped to the obtained values; and generating sensor data corresponding to the target object based on the obtained reflection rate.

### BACKGROUND

### 1. Technical Field

The disclosure relates to the field of autonomous driving simulation technology, and in particular, to an apparatus and a method of providing a simulation scenario in which actions of an autonomous vehicle can be relatively defined with a non-autonomous vehicle actor.

### 2. Description of Related Art

Autonomous driving vehicles include a number of systems that must interoperate in order to provide autonomous real-time control. Among these systems are sensors that are used to sense objects in the vehicle’s surroundings, based on which various perception and decision-making tasks are performed. For example, the sensors can sense and generate sensing data for an object (such as a pedestrian or a bicycle) that may obstruct the vehicle’s path. The sensing data is input to the autonomous driving vehicle stack, and autonomous driving software can detect and track the object, and can make a decision and affect control so as to avoid the obstruction.

Autonomous driving simulation systems are used to develop and safely deploy autonomous driving applications in the autonomous software stack. Autonomous driving simulation systems include three categories of tools or models that interoperate to provide a simulation for testing an application under development:

The core simulator is the primary simulation tool that creates, edits, and executes the scenario in which the simulation is run. Via the core simulation, the virtual world itself can be defined, as well as the actors and the actors’ movements. For example, the scenario may include a pedestrian and a non-autonomous vehicle that is moving at a particular speed over a particular trajectory to test how the autonomous vehicle will behave in such a scenario.

The vehicle simulator simulates the autonomous vehicle. The vehicle simulator includes (a) vehicle dynamics simulation that simulates the vehicles physical motion, (b) vehicle controller or units simulation that simulates various units of the vehicle (such as the engine, the battery, the air conditioner, etc.), and (c) vehicle body simulation that simulates components of the vehicle body (such as the lights, a door, warning lamps, etc.).

The sensor simulator simulates various sensors of the autonomous vehicle, such as the camera, LiDAR sensor, radar, etc. The sensor simulator, for example, outputs simulated camera images.

Active sensors, such as a LiDAR sensor, implemented in autonomous driving systems generate sensor data by transmitting light or waves (e.g., a laser beam) and receiving a reflection of that transmitted light that has bounced off of a surface of a target object. In other words, the transmitted light is bounced off of the surface of the object and received by the sensor, and its time of flight is measured to determine the distance to the target object.

The light rays or waves that reflect back to the sensor are random, particularly where the target object surface is complex with many angles, bumps, ridges, etc. For example, a moving motorcycle or bicycle wheel includes rotating spokes (or wires) with a cylindrical surface that reflects light randomly, depending on the point of the surface of the spoke from which the transmitted light is reflected. This presents a problem in simulating the sensor and the generating of sensor data. Namely, in creating the simulation, a great amount of time and computational complexity is needed to simulate every polygon in each stoke and all lights or waves reflected thereby. To implement such a simulation accurately greatly reduces the simulation speed and/or increases the computational and processing demand to calculate each reflection off of each polygon of the surface.

### SUMMARY

Apparatuses and methods consistent with the inventive concept(s) provide a simulation tool that simplifies the target object definition while still providing an accurate sensor simulation. Namely, the object in the simulation environment is defined by its shape, size, and reflection information. The reflection information is defined by material (e.g., defining how light is reflected) and texture (e.g., color information). Further, a reflection rate table is used to map a plurality of simple object definitions to a reflection rate for that object.

For example, in the case of a bicycle wheel, the object definitions used in the simulation include the number of wires or spokes on the wheel, the wheel speed, and the angle between the autonomous-vehicle (or sensor thereof) and the wheel. The values for these three items are input to a dynamic reflection rate table, which provides a three-dimensional mapping of these values to a dynamic reflection rate. The dynamic reflection rate represents the rate of reflected rays received by the sensor. The reflection rate table is provided or pre-determined based on real-time testing data samples.

According to an exemplary embodiment, a plurality of different dynamic reflection rate tables are prepared based on the reflection information (e.g., the material and/or the texture). In other words, each table is prepared based on sample data from real testing performed with respect to objects having different reflection information. The sensor simulator according to this embodiment therefore uses a dynamic reflection rate table that corresponds to the reflection material set for the object.

The reflection rate output from the reflection rate table is then used to calculate a point cloud for the target object, e.g., LiDAR point cloud. According to an embodiment, the reflection rate and the number of incoming rays are input to a random point function that calculates the ray points (e.g., 3 reflected or incoming rays and a reflection rate of 10%). Further, the vector and strength of each ray point are calculated or determined using any of various well-known techniques to generate a point cloud.

According to an exemplary embodiment of the disclosure, a method of simulating a sensor in an autonomous driving simulation includes obtaining values for a plurality of attributes of a target object to be sensed by a sensor simulator in the autonomous driving simulation, the sensor simulator simulating an active sensor that outputs rays to an object and receives reflections of the rays from the object; inputting the obtained values for the plurality of attributes to a predetermined reflection rate table, in order to obtain a reflection rate mapped to the obtained values; and generating sensor data corresponding to the target object based on the obtained reflection rate where the target object is a wheel and the plurality of attributes comprise a number of wheel spokes, a wheel speed, and an angle between the wheel and an autonomous vehicle in the autonomous driving simulation.

The method according to an exemplary embodiment may further include obtaining reflection information defined for the target object. The reflection information may include a texture and a material of a reflection surface of the target object.

Additionally, the method according to an exemplary embodiment may include inputting the values for the plurality of attributes to the predetermined reflection rate table and selecting the predetermined reflection rate table corresponding to the obtained reflection information, from among a plurality of predetermined rate tables respectively corresponding to different reflection information. The predetermined reflection rate table may be predetermined based on real world reflection rate testing to map values the plurality of attributes of the of the target object to dynamic reflection rates. Additionally, according to an exemplary embodiment of the disclosure, the generated sensor data comprises a point cloud for the target object.

According to yet another exemplary embodiment of the disclosure, the sensor data includes inputting the obtained reflection rate and a number of incoming reflected rays to a random point function to calculate ray points, and calculating a vector and a strength of each ray point.

According to another exemplary embodiment of the disclosure, a non-transitory computer-readable storage medium, storing instructions executable by at least one processor to perform a method where the method includes obtaining values for a plurality of attributes of a target object to be sensed by a sensor simulator in the autonomous driving simulation, the sensor simulator simulating an active sensor that outputs rays to an object and receives reflections of the rays from the object; inputting the obtained values for the plurality of attributes to a predetermined reflection rate table, in order to obtain a reflection rate mapped to the obtained values; and generating sensor data corresponding to the target object based on the obtained reflection rate. The target object being a wheel and the plurality of attributes being a number of wheel spokes, a wheel speed, and an angle between the wheel and an autonomous vehicle in the autonomous driving simulation.

### BRIEF DESCRIPTION OF THE DRAWINGS

Features, advantages, and technical and industrial significance of exemplary embodiments of the disclosure will be described below with reference to the accompanying drawings, in which like signs denote like elements. The various features of the drawings are not to scale as the illustrations are for clarity in facilitating the understanding of one skilled in the art in conjunction with the detailed description. In the drawings:

FIG. 1 is a block diagram illustrating a system for implementing an autonomous driving simulation according to an exemplary embodiment;

FIG. 2 is a diagram illustrating operation of a simulated sensor according to an exemplary embodiment; and

FIG. 3 is a flowchart illustrating a method of simulating a sensor in an autonomous driving simulation according to an exemplary embodiment.

### DETAILED DESCRIPTION

Embodiments of the disclosure will be described in detail with reference to the accompanying drawings. The same reference numerals used in the drawings may identify the same or similar elements. The terms used in the disclosure should not be strictly construed as defined in the disclosure, but should be construed as those one of ordinary skilled in the art would understand in the context of the disclosure. It should be noted that the embodiments of the disclosure may be in different forms and are not limited to the embodiments of the disclosure set forth herein.

Aspects are described herein with reference to flowchart illustrations and/or block diagrams of methods, apparatus (systems), and computer readable media according to the various embodiments. It will be understood that each block of the flowchart illustrations and/or block diagrams, and combinations of blocks in the flowchart illustrations and/or block diagrams, can be implemented by computer readable program instructions.

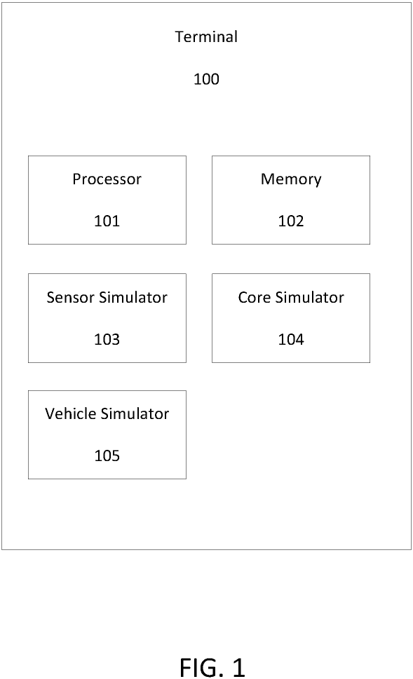

FIG. 1 is a flowchart illustrating a method of simulating a sensor in an autonomous driving simulation according to an exemplary embodiment.

Regarding FIG. 1, the terminal 100 may include a processor 101, a memory 102, and a sensor simulator 103. However, the terminal is not limited to the aforementioned components and may be configured to have more or less components than described herein.

The processor 101 may control an overall operation of the terminal 100. Specifically, the processor 102 may be connected to and configured to control the operations of the memory 102. For example, the processor 101 may be implemented as at least one of an application specific integrated circuit (ASIC), an embedded processor, a microprocessor, hardware control logic, a hardware finite state machine (FSM), a digital signal processor (DSP), a neural network processor (NPU), or the like. The processor 101 may include a central processing unit (CPU), a graphic processing unit (GPU), and a main processing unit (MPU), or the like. In addition, the processor 101 may include one or more processors.

The memory 102 may store at least one instruction and various software programs or applications for operating the terminal 100 according to embodiments of the disclosure. For example, the memory 102 may include a semiconductor memory, such as a flash memory, a magnetic storage medium such as a hard disk, or the like. The memory 102 may refer to any volatile or non-volatile memory, a read-only memory (ROM), a random access memory (RAM) communicatively coupled to the processor 101 or a memory card (e.g., a micro SD card, a memory stick) connectable to the terminal 100. Additionally, the memory 102 may include one or more memory units.

Specifically, the memory 102 may store various software modules or codes for operating the terminal 100, and the processor 101 may control the operations of the terminal 100 by executing various software modules that are stored in the memory 102. That is, the memory 102 may be accessed by the processor 101 to perform data reading, recording, modifying, deleting, updating or the like.

The memory 103 may store an autonomous driving operating system (OS) for autonomous control of a vehicle, such as an operating system executable on an electronic control unit (ECU) of a vehicle. The memory 102 may also store at least one application programming interface (API) to interface the OS with applications used for autonomous driving, including those applications that may be tested via the simulation method disclosed herein. Further, the memory 103 may store middleware for communication between the autonomous driving OS and simulation models, such as a sensor simulator 103, a core simulator 104, and a vehicle simulator 105, etc.

The memory 102 may also be configured to store various simulation models for providing an autonomous driving simulation architecture. For example, the memory 102 may store executable instructions, code, data objects, etc., corresponding to one or more one or more sensor simulators 103 (or sensor simulation models), one or more core simulators 104, and/or one or more vehicle simulators 105 (or vehicle simulation models).

The core simulator 104 may be a primary simulation tool that creates, edits and executes scenarios in which a simulation of an autonomous vehicle may be performed. For example, the core simulator 104 may define a virtual world or environment as well as the actors and the actors’ movements in the virtual environment. Specifically, the core simulator 104 may be configured to simulate a scenario to test how the autonomous vehicle will behave or operate in such a scenario. Here, the term autonomous vehicle may refer to a vehicle that is controlled by an automated driving system (ADS) or at least equipped with the ADS. The ADS may provide self-driving capabilities in which no physical action is required by an autonomous vehicle driver who may manually control the vehicle. The self-driving capabilities may include, for example, navigating or driving the vehicle using various sensors and software without human intervention.

The vehicle simulator 105 may be a model that simulates the autonomous vehicle. The vehicle simulator may include a vehicle dynamics simulation that simulates the vehicle’s physical motions, a vehicle controller or unit simulation that simulates various units of the vehicle (e.g., engine, battery, air conditioner, etc.), and a vehicle body simulation that simulates components of the vehicle body (e.g., lights, doors, warning lamps, etc.). The vehicle simulator 105 may be supplied by a car manufacturer and/or may correspond to a particular vehicle and the attributes thereof.

The sensor simulator 103 may be a model that simulates various sensors of the autonomous vehicle. The sensors that may be simulated by the sensor simulator 103 may include a camera, a LiDAR sensor, a radar sensor, etc. For example, the sensor simulator 103 may output camera images of the simulated scenes. The sensors that may be simulated by the sensor simulator 103 are not limited thereto, and may include other sensors that may be relevant to providing self-driving capabilities of the autonomous vehicle.

According to an exemplary embodiment, the sensor simulator 103, the core simulator 104, and the vehicle simulator 105 may be stored in the memory 102, or may be temporarily stored in the memory 102 to be processed by the processor 101. Alternatively, the sensor simulator 103, the core simulator 104, and the vehicle simulator 105 may be separate components within the terminal 100 that communicate with the processor 101 and the memory 102.

In addition, according to an exemplary embodiment, a method and a device disclosed herein may be provided as software of a computer program product. A computer program product may be distributed in the form of a machine readable storage medium (e.g., compact disc read only memory (CD-ROM)) or distributed online through an application store or between two devices directly. In the case of on-line distribution, at least a portion of the computer program product (e.g., a downloadable app) may be stored temporarily or at least temporarily in a storage medium such as a manufacturer’s server, a server in an application store, or a memory in a relay server.

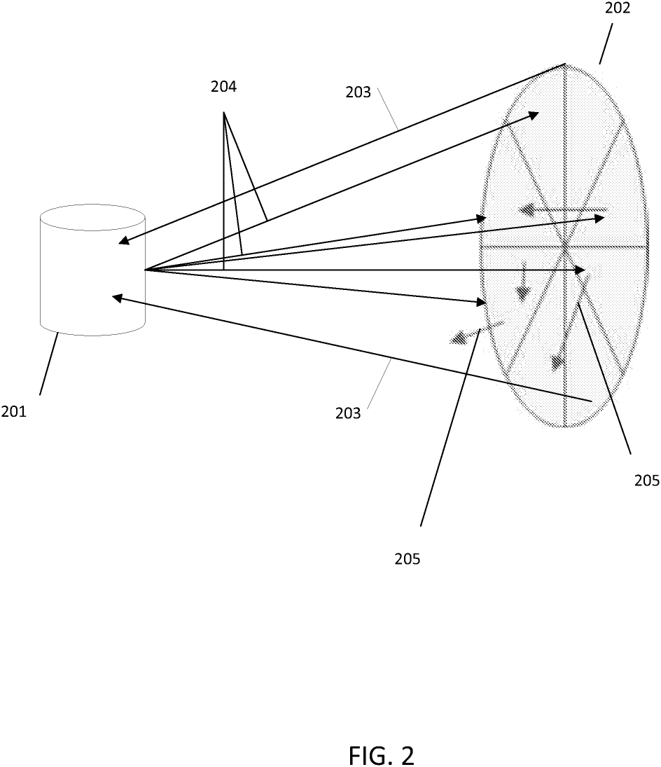

FIG. 2 is a diagram illustrating operation of a simulated sensor according to an exemplary embodiment.

Referring to FIG. 2, a sensor simulator according to an exemplary embodiment senses a target object in the autonomous driving simulation to determine a plurality of attributes of the target object. The sensor simulator may simulate an active sensor 201 that outputs output rays 204 to an object 202 and receives reflection rays 203 from the object. The simulated active sensor 201 may include a simulated LiDAR, radar, sonar, etc. That is, the simulated active sensor 201 may send light or waves 204 towards an object 202 and detect the light or waves 203 that are reflected back towards the sensor from the object. However, not all of the rays that are output towards the target object are reflected back to the sensor. As such, there exist a plurality of rays 205 that are reflected off of the target 202 that do not reach the simulated active sensor 201.

The target object may be a motorcycle, bicycle, unicycle, tricycle, or the like. However, the target object is not limited thereto and may be any object detectable by the sensor in a simulation. According to an embodiment of the disclosure as shown in FIG. 2, an object 202 is a wheel of a motorcycle or bicycle. The plurality of attributes of the aforementioned object 202 may include the number of wires in a wheel of the target object. One of the plurality of attributes may also include the wheel speed of the target object. Further, one of the plurality of attributes of the target object may be the angle between the simulated sensor 201 and the target object. That is, the angle between the simulated sensor 201 and the target object defines the area of the target object seen by the simulated sensor 201 when the object 202 is a wheel of a motorcycle or bicycle (e.g. is the sensor 201 facing the tread of the tire on the wheel, the spokes of the wheel, or a combination of both).

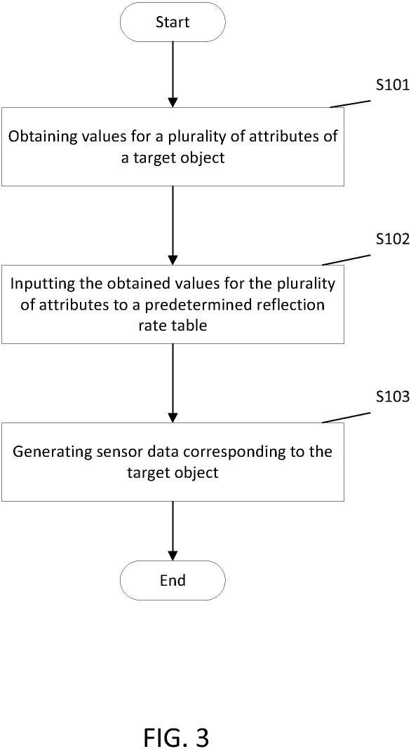

FIG. 3 is a flowchart illustrating a method of simulating a sensor in an autonomous driving simulation according to an exemplary embodiment.

According to an exemplary embodiment, the method of simulating a sensor in an autonomous driving simulation may be performed or controlled, via executing instructions, by the processor 101 of the terminal 100 (shown in FIG. 1).

Referring to FIG. 3, in step S101, a method performing an autonomous driving simulation for simulating a sensor according to an exemplary embodiment is provided. For example, the autonomous driving simulation executed on the terminal 100 by integrating the sensor simulator 103, the core simulator 104, and vehicle simulator 105 is provided. That is, the at least one processor 101 may access the memory 102 to execute instructions to conduct a simulation data with the sensor simulator 103, the core simulator 104, and vehicle simulator 105. In step S101, the processor is configured to access the memory to obtain values for a plurality of attributes of a target object to be sensed by a sensor simulator 103 in the autonomous driving simulation. The sensor simulator 103 simulates an active sensor that outputs rays 204 to an object and receives reflections 203 of the rays from the object. In the case that the object is a wheel of a bicycle, motorcycle, or the like, the plurality of attributes may include the number of wire spokes, the rotational speed of the wheel, and/or the angle between the autonomous vehicle (i.e. the active sensor) and the wheel.

In step S102, the obtained values for the plurality of attributes are input to a predetermined reflection rate table, in order to obtain a reflection rate mapped to the obtained values. Because the rays 204 output towards the object (e.g. a wheel on motorcycle or bicycle that includes wire spokes) are randomly reflected based on the number of wires, the wheel speed, and the angle between the autonomous vehicle (i.e. active sensor) and the object 202, a rate of reflection of rays that are reflected back towards the simulated sensor 201 can be determined using the predetermined reflection table.

The predetermined reflection rate table values may be provided or pre-determined based on real-time testing data samples. According to an exemplary embodiment of the disclosure, a plurality of different reflection rate tables may be prepared based on the reflection information gathered during real time testing of an object (e.g. a wheel on motorcycle or bicycle that includes wire spokes). Each of the plurality of reflection rate tables may represent a different reflection surface (e.g., the material and/or the texture). In other words, each table is prepared based on sample data from real testing performed with respect to objects having different reflection information. The sensor simulator according to an exemplary embodiment therefore uses a reflection rate table that corresponds to the reflection material set for the object. As such, the exemplary method described herein may also include obtaining reflection information for the target object. Additionally, the processor 101 may be further configured to pick a predetermined reflection rate table corresponding to the obtained refection information of the target object.

Regarding step S103, using the obtained reflection rate information in the predetermined reflection rate table, sensor data corresponding to the target object is generated. Specifically, according to an exemplary embodiment, the reflection rate output from the reflection rate table is used to calculate a point cloud for the target object, e.g., LiDAR point cloud or a radar point cloud. According to an exemplary embodiment, the reflection rate and the number of incoming rays are input to a random point function that calculates the ray points (e.g., 3 reflected or incoming rays and a reflection rate of 10%). Further, the vector and strength of each ray point are calculated or determined using any of various well-known techniques to generate a point cloud. The generated point may be displayed to a user via a graphical user interface, stored on the memory 102, uploaded to a remote server, or sent on a network to another terminal.

Because the exemplary embodiment uses a predetermined dynamic reflection rate table, the sensor simulator according to embodiments can simply calculate random reflections from a target object quickly and easily, without the computational complexity and excess computing resources required by related art simulations that define the target object by recreating its exact shape. This results in a simulation that can be run in a shorter time and reduces the computational complexity needed to simulate every polygon in each wire wheel stoke and all rays reflected thereby.

Some embodiments may relate to a system, a method, and/or a computer readable medium at any possible technical detail level of integration. The computer readable medium may include a computer-readable non-transitory storage medium (or media) having computer readable program instructions thereon for causing a processor to carry out operations.

The computer readable storage medium can be a tangible device that can retain and store instructions for use by an instruction execution device. The computer readable storage medium may be, for example, but is not limited to, an electronic storage device, a magnetic storage device, an optical storage device, an electromagnetic storage device, a semiconductor storage device, or any suitable combination of the foregoing. A non-exhaustive list of more specific examples of the computer readable storage medium includes the following: a portable computer diskette, a hard disk, a random access memory (RAM), a read-only memory (ROM), an erasable programmable read-only memory (EPROM or Flash memory), a static random access memory (SRAM), a portable compact disc read-only memory (CD-ROM), a digital versatile disk (DVD), a memory stick, a floppy disk, a mechanically encoded device such as punch-cards or raised structures in a groove having instructions recorded thereon, and any suitable combination of the foregoing. A computer readable storage medium, as used herein, is not to be construed as being transitory signals per se, such as radio waves or other freely propagating electromagnetic waves, electromagnetic waves propagating through a waveguide or other transmission media (e.g., light pulses passing through a fiber-optic cable), or electrical signals transmitted through a wire.

Computer readable program instructions described herein can be downloaded to respective computing/processing devices from a computer readable storage medium or to an external computer or external storage device via a network, for example, the Internet, a local area network, a wide area network and/or a wireless network. The network may comprise copper transmission cables, optical transmission fibers, wireless transmission, routers, firewalls, switches, gateway computers and/or edge servers. A network adapter card or network interface in each computing/processing device receives computer readable program instructions from the network and forwards the computer readable program instructions for storage in a computer readable storage medium within the respective computing/processing device.

Computer readable program code/instructions for carrying out operations may be assembler instructions, instruction-set-architecture (ISA) instructions, machine instructions, machine dependent instructions, microcode, firmware instructions, state-setting data, configuration data for integrated circuitry, or either source code or object code written in any combination of one or more programming languages, including an object oriented programming language such as Smalltalk, C++, or the like, and procedural programming languages, such as the “C” programming language or similar programming languages. The computer readable program instructions may execute entirely on the user’s computer, partly on the user’s computer, as a stand-alone software package, partly on the user’s computer and partly on a remote computer or entirely on the remote computer or server. In the latter scenario, the remote computer may be connected to the user’s computer through any type of network, including a local area network (LAN) or a wide area network (WAN), or the connection may be made to an external computer (for example, through the Internet using an Internet Service Provider). In some embodiments, electronic circuitry including, for example, programmable logic circuitry, field-programmable gate arrays (FPGA), or programmable logic arrays (PLA) may execute the computer readable program instructions by utilizing state information of the computer readable program instructions to personalize the electronic circuitry, in order to perform aspects or operations.

These computer readable program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks. These computer readable program instructions may also be stored in a computer readable storage medium that can direct a computer, a programmable data processing apparatus, and/or other devices to function in a particular manner, such that the computer readable storage medium having instructions stored therein comprises an article of manufacture including instructions which implement aspects of the function/act specified in the flowchart and/or block diagram block or blocks.

The computer readable program instructions may also be loaded onto a computer, other programmable data processing apparatus, or other device to cause a series of operational steps to be performed on the computer, other programmable apparatus or other device to produce a computer implemented process, such that the instructions which execute on the computer, other programmable apparatus, or other device implement the functions/acts specified in the flowchart and/or block diagram block or blocks.

The flowchart and block diagrams in the Figures illustrate the architecture, functionality, and operation of possible implementations of systems, methods, and computer readable media according to various embodiments. In this regard, each block in the flowchart or block diagrams may represent a module, segment, or portion of instructions, which comprises one or more executable instructions for implementing the specified logical function(s). The method, computer system, and computer readable medium may include additional blocks, fewer blocks, different blocks, or differently arranged blocks than those depicted in the Figures. In some alternative implementations, the functions noted in the blocks may occur out of the order noted in the Figures. For example, two blocks shown in succession may, in fact, be executed concurrently or substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

It will be apparent that systems and/or methods, described herein, may be implemented in different forms of hardware, firmware, or a combination of hardware and software. The actual specialized control hardware or software code used to implement these systems and/or methods is not limiting of the implementations. Thus, the operation and behavior of the systems and/or methods were described herein without reference to specific software code-it being understood that software and hardware may be designed to implement the systems and/or methods based on the description herein.

No element, act, or instruction used herein should be construed as critical or essential unless explicitly described as such. Also, as used herein, the articles “a” and “an” are intended to include one or more items, and may be used interchangeably with “one or more.” Furthermore, as used herein, the term “set” is intended to include one or more items (e.g., related items, unrelated items, a combination of related and unrelated items, etc.), and may be used interchangeably with “one or more.” Where only one item is intended, the term “one” or similar language is used. Also, as used herein, the terms “has,” “have,” “having,” or the like are intended to be open-ended terms. Further, the phrase “based on” is intended to mean “based, at least in part, on” unless explicitly stated otherwise.

The descriptions of the various aspects and embodiments have been presented for purposes of illustration, but are not intended to be exhaustive or limited to the embodiments disclosed. Even though combinations of features are recited in the claims and/or disclosed in the specification, these combinations are not intended to limit the disclosure of possible implementations. In fact, many of these features may be combined in ways not specifically recited in the claims and/or disclosed in the specification. Although each dependent claim listed below may directly depend on only one claim, the disclosure of possible implementations includes each dependent claim in combination with every other claim in the claim set. Many modifications and variations will be apparent to those of ordinary skill in the art without departing from the scope of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A method of simulating a sensor in an autonomous driving simulation, the method comprising:
obtaining values for a plurality of attributes of a target object to be sensed by a sensor simulator in the autonomous driving simulation, the sensor simulator simulating an active sensor that outputs rays to an object and receives reflections of the rays from the object;
inputting the obtained values for the plurality of attributes to a predetermined reflection rate table, in order to obtain a reflection rate mapped to the obtained values; and
generating sensor data corresponding to the target object based on the obtained reflection rate,
wherein the target object is a wheel and the plurality of attributes comprise a number of wheel spokes, a wheel speed, and an angle between the wheel and an autonomous vehicle in the autonomous driving simulation.

2. The method of claim 1, further comprising obtaining reflection information defined for the target object.

3. The method of claim 2, wherein the reflection information comprises a texture and a material of a reflection surface of the target object.

4. The method of claim 2, wherein the inputting the values for the plurality of attributes to the predetermined reflection rate table comprises selecting the predetermined reflection rate table, corresponding to the obtained reflection information, from among a plurality of predetermined rate tables respectively corresponding to different reflection information.

5. The method of claim 1, wherein the predetermined reflection rate table is predetermined based on real world reflection rate testing to map values the plurality of attributes of the of the target object to dynamic reflection rates.

6. The method of claim 1, wherein the generated sensor data comprises a point cloud for the target object.

7. The method of claim 1, wherein the generating the sensor data comprises inputting the obtained reflection rate and a number of incoming reflected rays to a random point function to calculate ray points, and calculating a vector and a strength of each ray point.

8. An autonomous driving simulator comprising:
at least one memory configured to store computer program code; and
at least one processor configured to execute the computer program code to:
obtain values for a plurality of attributes of a target object to be sensed by a sensor simulator in the autonomous driving simulator, the sensor simulator simulating an active sensor that outputs rays to an object and receives reflections of the rays from the object,
input the obtained values for the plurality of attributes to a predetermined reflection rate table, in order to obtain a reflection rate mapped to the obtained values, and
generate sensor data corresponding to the target object based on the obtained reflection rate,
wherein the target object is a wheel and the plurality of attributes comprise a number of wheel spokes, a wheel speed, and an angle between the wheel and an autonomous vehicle in the autonomous driving simulator.

9. The autonomous driving simulator of claim 8, wherein the at least one processor is further configured to execute the computer program code to obtain reflection information defined for the target object.

10. The autonomous driving simulator of claim 9, wherein the reflection information comprises a texture and a material of a reflection surface of the target object.

11. The autonomous driving simulator of claim 9, wherein the at least one processor is further configured to execute the computer program code to input the values for the plurality of attributes to the predetermined reflection rate table by selecting the predetermined reflection rate table, corresponding to the obtained reflection information, from among a plurality of predetermined rate tables respectively corresponding to different reflection information.

12. The autonomous driving simulator of claim 8, wherein the predetermined reflection rate table is predetermined based on real world reflection rate testing to map values the plurality of attributes of the of the target object to dynamic reflection rates.

13. The autonomous driving simulator of claim 8, wherein the generated sensor data comprises a point cloud for the target object.

14. The autonomous driving simulator of claim 13, wherein the generating the sensor data comprises inputting the obtained reflection rate and a number of incoming reflected rays to a random point function to calculate ray points, and calculating a vector and a strength of each ray point.

15. A non-transitory computer-readable storage medium, storing instructions executable by at least one processor to perform a method comprising:
obtaining values for a plurality of attributes of a target object to be sensed by a sensor simulator, the sensor simulator simulating an active sensor that outputs rays to an object and receives reflections of the rays from the object;
inputting the obtained values for the plurality of attributes to a predetermined reflection rate table, in order to obtain a reflection rate mapped to the obtained values; and
generating sensor data corresponding to the target object based on the obtained reflection rate,
wherein the target object is a wheel and the plurality of attributes comprise a number of wheel spokes, a wheel speed, and an angle between the wheel and an autonomous vehicle.
